(19) United States
(12) Patent Application Publication
(10) Pub. No.: US 2026/0066007 A1
(43) Pub. Date: Mar. 5, 2026

(54) POWER SUPPLY DEVICE AND MEMORY SYSTEM

(71) Applicant: Kioxia Corporation, Tokyo (JP)

(72) Inventor: Ryo TAKEUCHI, Kawasaki (JP)

(73) Assignee: Kioxia Corporation, Tokyo (JP)

(21) Appl. No.: 19/061,092

(22) Filed: Feb. 24, 2025

(30) Foreign Application Priority Data
Sep. 2, 2024 (JP) 2024-150747

(51) Int. Cl. G11C 16/30; G06F 1/3296; G11C 16/04

(52) U.S. Cl. CPC G11C 16/30; G06F 1/3296; G11C 16/0483

(57) ABSTRACT

According to embodiments, a power supply device includes a power management integrated circuit (PMIC) and a plurality of voltage output terminals. The PMIC includes a plurality of channels for outputting voltages and is capable of notifying an outside of output abnormality of at least one of the plurality of channels. The plurality of voltage output terminals include a first voltage output terminal coupled to a first channel among the plurality of channels. In a case of detecting output abnormality of the first channel, the PMIC is configured to stop output of a first voltage from the first channel to the first voltage output terminal, electrically couple a second channel different from the first channel among the plurality of channels to the first voltage output terminal, and output a second voltage from the second channel to the first voltage output terminal.

### CROSS-REFERENCE TO RELATED APPLICATIONS

This application is based upon and claims the benefit of priority from Japanese Patent Application No. 2024-150747, filed Sep. 2, 2024, the entire contents of which are incorporated herein by reference.

### FIELD

Embodiments described herein relate generally to a power supply device and a memory system.

### BACKGROUND

A power supply device and a memory system including a power management integrated circuit (PMIC) are known.

### BRIEF DESCRIPTION OF THE DRAWINGS

FIG. 1 is a block diagram illustrating an example of the configuration of a data processing device including a memory system according to a first embodiment.

FIG. 2 is a block diagram illustrating an example of the configuration of a non-volatile memory included in the memory system according to the first embodiment.

FIG. 3 is a circuit diagram illustrating an example of the circuit configuration of a memory cell array included in the memory system according to the first embodiment.

FIG. 4 is a circuit diagram illustrating an example of the circuit configuration of a power supply device according to the first embodiment.

FIG. 5 is a diagram illustrating the specific example of the power supply device in a state where a PMIC according to the first embodiment detects output abnormality.

FIG. 6 is a circuit diagram illustrating an example of the circuit configuration of a power supply device according to a second embodiment.

FIG. 7 is a diagram illustrating the specific example of the power supply device in a state where a PMIC according to the second embodiment detects output abnormality.

FIG. 8 is a circuit diagram illustrating an example of the circuit configuration of a power supply device according to a third embodiment.

FIG. 9 is a diagram illustrating the specific example of the power supply device in a state where a PMIC according to the third embodiment detects output abnormality.

### DETAILED DESCRIPTION

In general, according to one embodiment, a power supply device includes a power management integrated circuit (PMIC) and a plurality of voltage output terminals. The PMIC includes a plurality of channels for outputting voltages and is capable of notifying an outside of output abnormality of at least one of the plurality of channels. The plurality of voltage output terminals include a first voltage output terminal coupled to a first channel among the plurality of channels. In a case of detecting output abnormality of the first channel, the PMIC is configured to stop output of a first voltage from the first channel to the first voltage output terminal, electrically couple a second channel different from the first channel among the plurality of channels to the first voltage output terminal, and output a second voltage from the second channel to the first voltage output terminal.

Hereinafter, embodiments will be described with reference to the drawings. In the following description, a common reference numeral is given to components having the same function and configuration. In a case of distinguishing a plurality of components having a common reference numeral, subscripts are given to the common reference numeral to distinguish the plurality of components. In a case where there is no particular need to distinguish between a plurality of components, only a common reference numeral is given to the plurality of components, and no subscripts are given to the plurality of components. Here, the subscript is not limited to subscripts or superscripts, but includes, for example, a lowercase alphabet added to the end of a reference numeral, an index that means an arrangement, and the like.

In the present specification and claims, a certain first element “being coupled” to another second element includes that the first element is coupled to the second element directly, or normally or selectively via a conductive element.

### 1. First Embodiment

A power supply device according to a first embodiment will be described. Hereinafter, the power supply device mounted on a memory system will be described as an example of the power supply device. The power supply device can also be applied to other semiconductor devices other than the memory system.

### 1.1 Configuration

### 1.1.1 Configuration of Data Processing Device

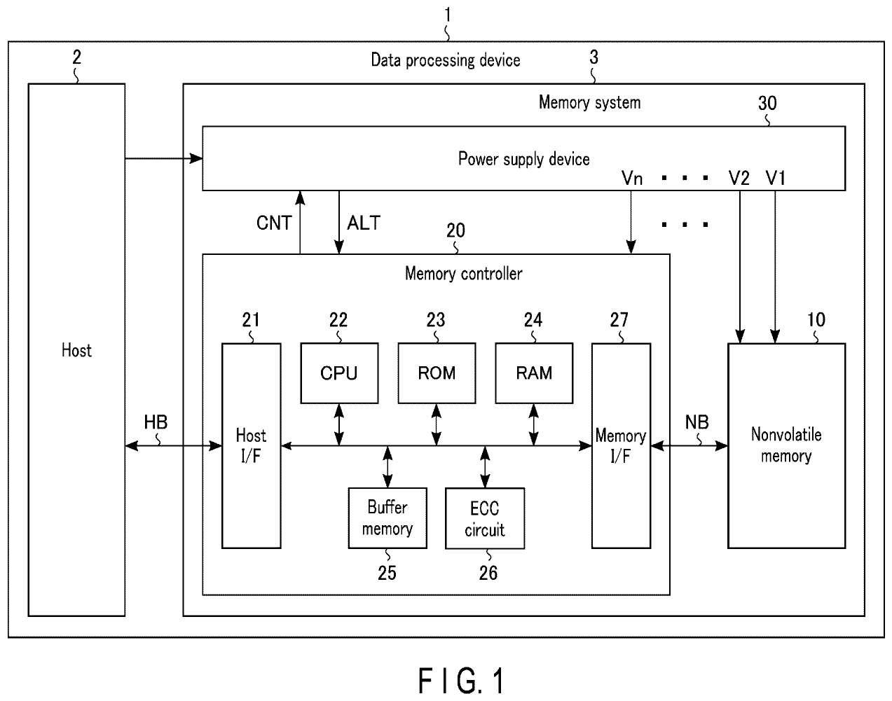

First, an example of the configuration of a data processing device including a memory system will be described with reference to FIG. 1. FIG. 1 is a block diagram illustrating an example of the configuration of a data processing device 1 including a memory system 3.

As illustrated in FIG. 1, the data processing device 1 includes a host 2 and a memory system 3. The data processing device 1 may include a plurality of hosts 2 or a plurality of memory systems 3. In a case where the data processing device 1 includes the plurality of hosts 2 and the plurality of memory systems 3, the plurality of memory systems 3 may be coupled to one host 2. The plurality of hosts 2 may be coupled to one memory system 3.

The host 2 is an information processing device (computing device) that accesses the memory system 3. The host 2 controls the memory system 3. More specifically, for example, the host 2 requests (instructs) the memory system 3 to perform a write operation or read operation of data (hereinafter, referred to as “user data”). The host 2 transmits and receives data and various signals to and from the memory system 3 via a host bus HB. The host 2 supplies a power supply voltage to a power supply device 30 of the memory system 3.

The memory system 3 is, for example, a solid state drive (SSD). The memory system 3 is coupled to the host 2 via the host bus HB. The type of the host bus HB depends on an application applied to the memory system 3. In a case where the memory system 3 is the SSD, the host bus HB conforms to, for example, Peripheral Component Interconnect Express (PCIe™) standard. The memory system 3 executes processing based on a request signal received from the host 2 or a voluntary processing request.

### 1.1.2 Configuration of Memory System

Next, an example of the configuration of the memory system 3 will be described with reference to FIG. 1. The memory system 3 includes a non-volatile memory 10, a memory controller 20, and a power supply device 30.

The non-volatile memory 10 is a non-volatile memory medium (semiconductor memory device). The non-volatile memory 10 may include a plurality of memory chips. Hereinafter, a case where the non-volatile memory 10 is a NAND flash memory will be described. The non-volatile memory 10 may be a non-volatile memory medium other than a NAND flash memory. The non-volatile memory 10 is coupled to the memory controller 20 via a NAND bus NB. The non-volatile memory 10 stores data received from the memory controller 20 in a non-volatile manner.

The memory controller 20 is, for example, a system on a chip (SoC). The memory controller 20 instructs the non-volatile memory 10 to perform a read operation, a write operation, an erase operation, and the like based on a request (instruction) from the host 2. The memory controller 20 manages a memory area of the non-volatile memory 10.

The power supply device 30 decreases the power supply voltage supplied from the host 2 and supplies a power supply voltage of a desired voltage to the non-volatile memory 10 and the memory controller 20. In the example illustrated in FIG. 1, the power supply device 30 generates voltages V1, V2, . . . , and Vn (n is an integer of 2 or more). For example, the power supply device 30 supplies the voltages V1 and V2 to the non-volatile memory 10 and supplies the voltage Vn to the memory controller 20. The power supply device 30 transmits a signal ALT for providing notification of the abnormality of an output voltage to the memory controller 20.

Next, an example of the internal configuration of the memory controller 20 will be described.

The memory controller 20 includes a host interface circuit (host I/F) 21, a central processing unit (CPU) 22, a read only memory (ROM) 23, a random access memory (RAM) 24, a buffer memory 25, an error check and correction (ECC) circuit 26, and a memory interface circuit (memory I/F) 27. These circuits are coupled to each other via an internal bus. The functions of the host interface circuit 21, the ECC circuit 26, and the memory interface circuit 27 may be implemented by a dedicated circuit or may be implemented by the CPU 22 executing firmware.

The host interface circuit 21 is an interface circuit coupled to the host 2 via the host bus HB. The host interface circuit 21 controls communication between the host 2 and the memory controller 20. The host interface circuit 21 transmits a request and user data received from the host 2 to the CPU 22 and the buffer memory 25, respectively. The host interface circuit 21 transmits the user data in the buffer memory 25 to the host 2 under the control of the CPU 22.

The CPU 22 is a processor. The CPU 22 controls the entire operation of the memory controller 20. For example, the CPU 22 instructs the non-volatile memory 10 to perform a write operation, a read operation, an erase operation, and the like based on a request of the host 2. The CPU 22 manages a memory space of the non-volatile memory 10. The CPU 22 transmits a control signal CNT to the power supply device 30 to control the power supply device 30.

The ROM 23 is a non-volatile memory. For example, the ROM 23 is an electrically erasable programmable read-only memory (EEPROM™). The ROM 23 is a non-transitory memory medium that stores firmware, programs, and the like. For example, the CPU 22 loads firmware from the ROM 23 to the RAM 24 and executes it.

The RAM 24 is a volatile memory. The RAM 24 is a dynamic random access memory (DRAM), a static random access memory (SRAM), or the like. The RAM 24 is used as a work area of the CPU 22. The RAM 24 stores firmware for managing the non-volatile memory 10, various kinds of management tables, and the like.

The buffer memory 25 is a volatile semiconductor memory. The buffer memory 25 is a DRAM, an SRAM, or the like. The buffer memory 25 temporarily stores user data, writing data, reading data, and the like.

The ECC circuit 26 is a circuit that executes ECC processing. The ECC processing includes encoding and decoding of data. The encoding is an operation of generating a code word based on data. For example, the ECC circuit 26 generates an error correction code (hereinafter, also referred to as “parity”) based on the user data. The ECC circuit 26 adds the parity to the user data to generate a code word, that is, writing data. The decoding is an operation of performing error correction of data. The ECC circuit 26 decodes data read from the non-volatile memory 10.

The memory interface circuit 27 controls communication between the memory controller 20 and the non-volatile memory 10. The memory interface circuit 27 is coupled to the non-volatile memory 10 via the NAND bus NB. The memory interface circuit 27 transmits and receives data, commands, addresses, and various control signals to and from the non-volatile memory 10 under the control of the CPU 22. More specifically, for example, at the time of the write operation, the memory interface circuit 27 transmits the writing data in the buffer memory 25, the addresses, the write commands, and various control signals to the non-volatile memory 10.

The memory interface circuit 27 transmits the addresses, the read commands, and various control signals to the non-volatile memory 10, for example, at the time of the read operation. The memory interface circuit 27 transmits data read from the non-volatile memory 10 to the buffer memory 25.

### 1.1.3 Configuration of Non-Volatile Memory

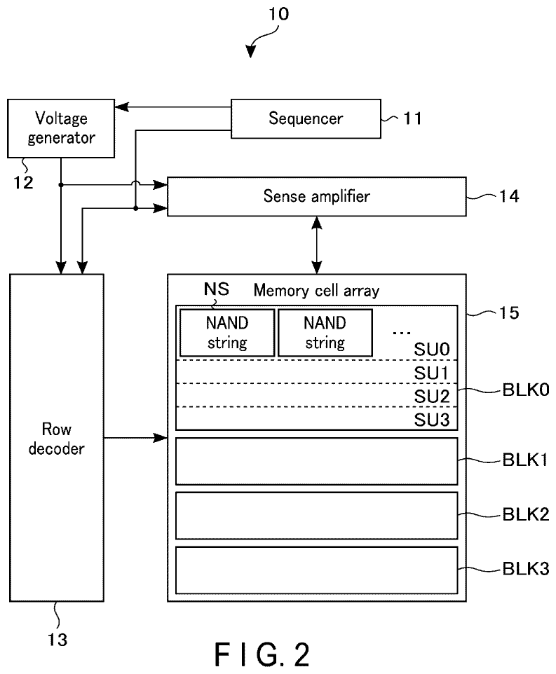

Next, an example of the overall configuration of the non-volatile memory 10 will be described with reference to FIG. 2. FIG. 2 is a block diagram illustrating an example of the configuration of the non-volatile memory 10.

As illustrated in FIG. 2, the non-volatile memory 10 includes a sequencer 11, a voltage generator 12, a row decoder 13, a sense amplifier 14, and a memory cell array 15.

The sequencer 11 controls the entire operation of the non-volatile memory 10. The sequencer 11 controls the voltage generator 12, the row decoder 13, the sense amplifier 14, and the like. The sequencer 11 executes a write operation, a read operation, an erase operation, and the like.

A power supply voltage is supplied from the power supply device 30 to the voltage generator 12. The voltage generator 12 generates voltages to be used for the write operation, the read operation, and the erase operation under the control of the sequencer 11, and supplies the voltages to the row decoder 13, the sense amplifier 14, and the like.

The row decoder 13 decodes, for example, an address (row address) received from the memory controller 20. The row decoder 13 selects any of blocks BLK based on the decoding result and supplies the voltage to the selected block BLK.

The sense amplifier 14 senses data read from any of string units SU of any of the blocks BLK at the time of the read operation. The sense amplifier 14 supplies voltages corresponding to writing data to the memory cell array 15 at the time of the write operation. The memory cell array 15 is a set of a plurality of memory cell transistors (hereinafter, also referred to as a “memory cell”) arranged in a two-dimensional or three-dimensional matrix. The memory cell array 15 includes a plurality of blocks BLK. In the example illustrated in FIG. 2, the memory cell array 15 includes four blocks BLK0 to BLK3. The block BLK is, for example, a set of a plurality of memory cell transistors from which data is collectively erased. That is, the block BLK is a data erasing unit. Each block BLK includes a plurality of string units SU. In the example shown in FIG. 2, the block BLK includes four string units SU0 to SU3. The string unit SU is a set of a plurality of NAND strings in which a plurality of memory cell transistors are coupled in series. The number of the blocks BLK in the memory cell array 15, the number of the string units SU in the block BLK, and the number of the NAND string NS in the string unit SU are arbitrary.

### 1.1.4 Circuit Configuration of Memory Cell Array

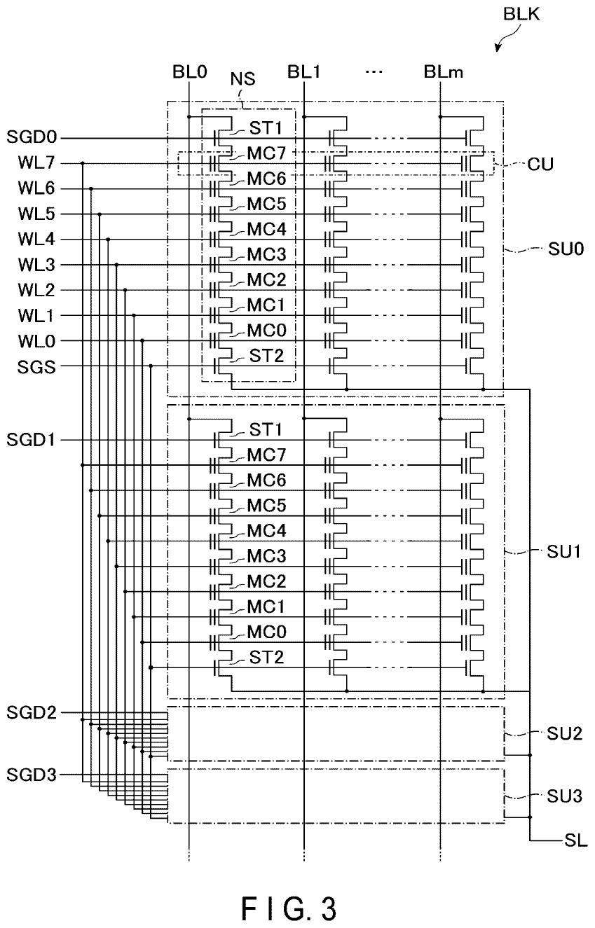

Next, the circuit configuration of the memory cell array 15 will be described with reference to FIG. 3. FIG. 3 is a circuit diagram illustrating an example of the circuit configuration of the memory cell array 15.

The example illustrated in FIG. 3 illustrates one block BLK, but the configurations of the other blocks BLK are also the same.

As illustrated in FIG. 3, each block BLK includes, for example, four string units SU0 to SU3. Each string unit SU includes a plurality of NAND strings NS. Each of the plurality of NAND strings NS in the string unit SU is coupled to any of bit lines BL0 to BLm (m is an integer of 1 or more). Each NAND string NS includes, for example, eight memory cell transistors MC (MC0 to MC7) and selection transistors ST1 and ST2. The number of the memory cell transistors MC in the NAND string NS is not limited to eight. The numbers of the selection transistors ST1 and ST2 in the NAND string NS may be one or more.

The memory cell transistor MC is a memory element that stores data in a non-volatile manner. The memory cell transistor MC includes a control gate and a charge storage layer. The memory cell transistor MC may be a metal-oxide-nitride-oxide-silicon (MONOS) type in which an insulator is used for the charge storage layer, or may be a floating gate (FG) type in which a conductor is used for the charge storage layer.

The selection transistors ST1 and ST2 are switching elements. The selection transistors ST1 and ST2 are used to select the string units SU at the time of various operations, respectively.

The current paths of the selection transistor ST2, the memory cell transistors MC0 to MC7, and the selection transistor ST1 in the NAND string NS are coupled in series. The drain of the selection transistor ST1 is coupled to the bit line BL. The source of the selection transistor ST2 is coupled to a source line SL. The control gates of the memory cell transistors MC0 to MC7 in the same block BLK are commonly coupled to word lines WL0 to WL7, respectively. More specifically, for example, each of the string units SU0 to SU3 includes a plurality of memory cell transistors MC0. The control gates of the plurality of memory cell transistors MC0 included in the string units SU0 to SU3 are commonly coupled to one word line WL0. That is, the control gates of the plurality of memory cell transistors MC0 in the block BLK are commonly coupled to one word line WL0. The same applies to the memory cell transistors MC1 to MC7.

The gates of the plurality of selection transistors ST1 in each string unit SU are commonly coupled to one select gate line SGD. More specifically, the gates of the plurality of selection transistors ST1 in the string unit SU0 are commonly coupled to a select gate line SGD0. The gates of the plurality of selection transistors ST1 in the string unit SU1 are commonly coupled to a select gate line SGD1. The gates of the plurality of selection transistors ST1 in the string unit SU2 are commonly coupled to a select gate line SGD2. The gates of the plurality of selection transistors ST1 in the string unit SU3 are commonly coupled to a select gate line SGD3.

The gates of the plurality of selection transistors ST2 in the block BLK are commonly coupled to a select gate line SGS.

The word lines WL0 to WL7, the select gate lines SGD0 to SGD3, and the select gate line SGS are coupled to the row decoder 13.

Each bit line BL is commonly coupled to one NAND string NS in each of the plurality of string units SU of each block BLK. Each bit line BL is coupled to the sense amplifier 14.

The source line SL is shared by, for example, the plurality of blocks BLK.

A set of the plurality of memory cell transistors MC coupled to the common word line WL in one string unit SU is referred to as, for example, a “cell unit CU”. In other words, the cell unit CU is a set of the plurality of memory cell transistors MC collectively selected in the write operation or the read operation. A page is a unit of data collectively written (or collectively read) in the cell unit CU. For example, in a case where the memory cell transistor MC stores 1-bit data, the memory capacity of the cell unit CU is one page. That is, the cell unit CU stores one-page data. The cell unit CU may have the memory capacity of two or more pages based on the number of bits of data stored in the memory cell transistor MC.

### 1.1.5 Configuration of Power Supply Device

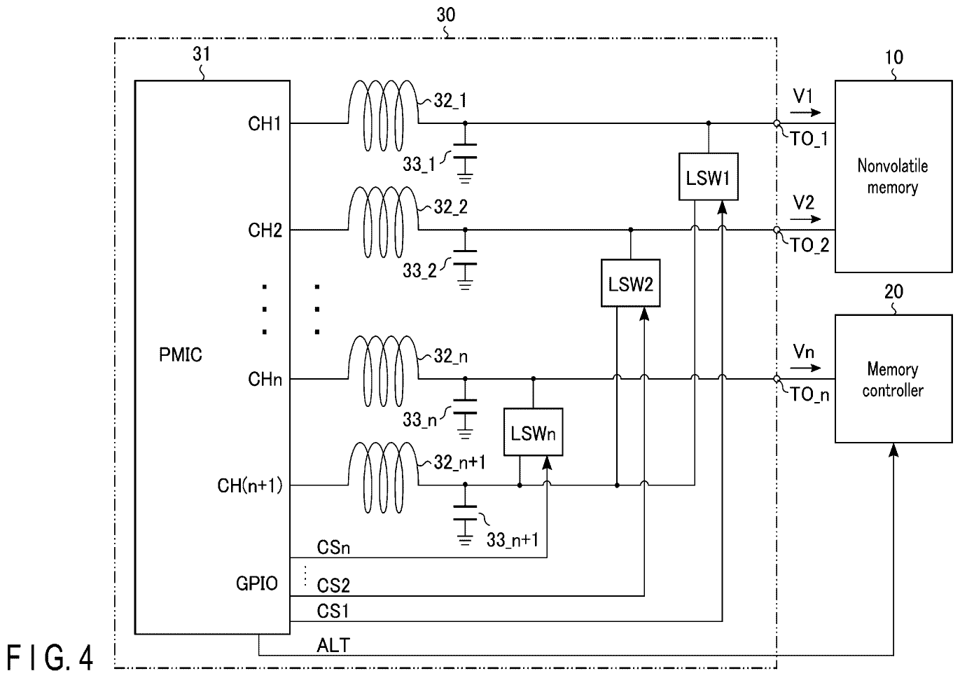

Next, an example of the configuration of the power supply device 30 will be described with reference to FIG. 4. FIG. 4 is a circuit diagram illustrating an example of the circuit configuration of the power supply device 30.

As illustrated in FIG. 4, the power supply device 30 includes a power management integrated circuit (PMIC) 31, a plurality of load switches LSW, a plurality of inductor elements 32, a plurality of capacitor elements 33, and a plurality of voltage output terminals TO. In the example illustrated in FIG. 4, the power supply device 30 includes n load switches LSW1 to LSWn, n+1 inductor elements 32_1 to 32_(n+1), n+1 capacitor elements 33_1 to 33_(n+1), and n voltage output terminals TO_1 to TO_n.

For example, the non-volatile memory 10, the memory controller 20, the PMIC 31, the load switches LSW, the inductor elements 32, and the capacitor elements 33 are individually mounted on a printed circuit board.

The PMIC 31 is an IC chip that manages a power supply voltage. The PMIC 31 of the present embodiment manages the power supply voltage output to the non-volatile memory 10 and the memory controller 20.

The PMIC 31 includes a plurality of channels CH for decreasing an input voltage input from the host 2 to a desired voltage value and outputting the input voltage. The PMIC 31 includes a buck converter (DCDC converter) or a constant voltage circuit (for example, LDO: LOW Dropout) corresponding to each channel CH (not illustrated). In the present embodiment, the number of the channels CH of the PMIC 31 is larger than the number of the voltage output terminals TO of the power supply device 30. The surplus channel CH with respect to the number of the voltage output terminals TO is used for compensating an output voltage. Hereinafter, the surplus channel CH is also referred to as a “redundant channel”.

More specifically, in the example illustrated in FIG. 4, the power supply device 30 outputs voltages V1 to Vn from the n voltage output terminals TO_1 to TO_n, respectively. Meanwhile, the PMIC 31 includes n+1 channels CH. The PMIC 31 may include n+1 or more channels CH.

The n channels CH1 to CHn are coupled to the n voltage output terminals TO_1 to TO_n of the power supply device 30, respectively. The n voltage output terminals TO_1 to TO_n are coupled to either the non-volatile memory 10 or the memory controller 20. That is, the n channels CH1 to CHn are coupled to either the non-volatile memory 10 or the memory controller 20. For example, the channel CH1 is coupled to the non-volatile memory 10 via the voltage output terminal TO_1. The PMIC31 supplies the voltage V1 to the non-volatile memory 10 via the channel CH1. The channel CH2 is coupled to the non-volatile memory 10 via the voltage output terminal TO_2. The PMIC 31 supplies the voltage V2 to the non-volatile memory 10 via the channel CH2. The channel CHn is coupled to the memory controller 20 via the voltage output terminal TO. The PMIC 31 supplies the voltage Vn to the memory controller 20 via the channel CHn.

The channel CH (n+1) is a surplus channel CH used for compensating the output voltage. That is, the PMIC 31 of the present embodiment includes a redundant portion including a redundant channel CH (n+1). The redundant channel CH (n+1) is coupled to the voltage output terminals TO_1 to TO_n via the load switches LSW1 to LSWn, respectively.

In a case of detecting the abnormality (output abnormality) of the voltage output from any of the channels CH1 to CHn, the PMIC 31 stops the output of the voltage from the channel CH. The PMIC 31 outputs the corresponding voltage using the redundant channel CH (n+1) instead of the channel CH in which the abnormality is detected.

The PMIC 31 has a signal output function of general purpose input output (GPIO). For example, the PMIC31 outputs control signals CS1 to CSn for controlling the load switches LSW1 to LSWn, respectively. For example, in a case where the load switch LSW is turned on, the control signal CS has a Low (“L”) level to a High (“H”) level.

The PMIC 31 has a function of notifying the outside of the power supply device 30 of the output abnormality. The PMIC 31, that is, the power supply device 30 transmits a signal ALT for providing notification of the output abnormality to the memory controller 20, for example. For example, in a case where the abnormality is detected, the signal ALT has a “L” level to a “H” level. For example, the memory controller 20 notifies a user of the data processing device 1 of the occurrence of the abnormality in the power supply device 30 via the host 2. For example, the user backs up data stored in the non-volatile memory 10, so that a situation in which data stored in the non-volatile memory 10 cannot be read due to the failure of the power supply device 30 can be avoided.

The load switch LSW is a circuit that electrically couples the redundant channel CH (n+1) and the voltage output terminal TO to each other based on the control signal CS. In the present embodiment, one terminal of each of the n load switches LSW1 to LSWn is coupled to the redundant channel CH (n+1). The other terminals of the n load switches LSW1 to LSWn are coupled to the n channels CH1 to CHn, respectively. For example, each load switch LSW is turned on in a case where the control signal CS having a “H” level is input. More specifically, for example, the load switch LSW1 is turned on in a case where the control signal CS1 having a “H” level is input, and electrically couples the redundant channel CH (n+1) and the voltage output terminal TO_1 to each other. Similarly, the load switch LSW2 is turned on in a case where the control signal CS2 having a “H” level is input, and electrically couples the redundant channel CH (n+1) and the voltage output terminal TO_2 to each other. The load switch LSWn is turned on in a case where the control signal CSn having a “H” level is input, and electrically couples the redundant channel CH (n+1) and the voltage output terminal TO_n to each other.

The inductor element 32 and the capacitor element 33 are used as filters for smoothing the voltage output from the corresponding channel CH. One set of the inductor element 32 and the capacitor element 33 is coupled to one channel CH. More specifically, one end of the inductor element 32_1 is coupled to the channel CH1, and the other end is coupled to one electrode of the capacitor element 33 and the voltage output terminal TO_1. The other electrode of the capacitor element 33 is grounded (coupled to a ground voltage interconnect). Similarly, the inductor element 32_2 and the capacitor element 33_2 are coupled between the channel CH2 and the voltage output terminal TO_2. The inductor element 32_n and the capacitor element 33_n are coupled between the channel CHn and the voltage output terminal TO_n. The inductor element 32_(n+1) and the capacitor element 33 (n+1) are coupled to the redundant channel CH (n+1).

### 1.2 Specific Example in Case where PMIC Detects Output Abnormality

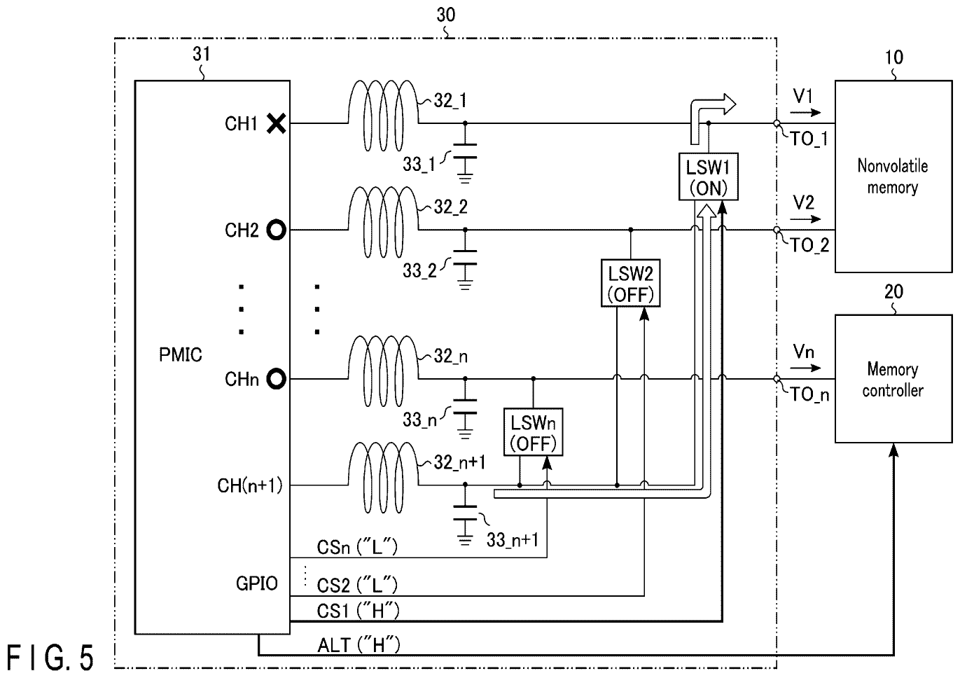

Next, a specific example in a case where the PMIC 31 detects the output abnormality will be described with reference to FIG. 5. FIG. 5 is a diagram illustrating the specific example of the power supply device 30 in a state where the PMIC 31 detects the output abnormality.

As illustrated in FIG. 5, for example, in a case where abnormality is detected in the output voltage of the channel CH1, the PMIC 31 stops the output of the voltage V1 from the channel CH1.

In this state, for example, the PMIC 31 sets the control signal CS1 to the “H” level and turns on the load switch LSW1. The PMIC 31 sets the other control signals CS2 to CSn to the “L” level and turns off the load switches LSW2 to LSWn. As a result, the redundant channel CH (n+1) and the voltage output terminal TO_1 are electrically coupled to each other. The PMIC 31 supplies the voltage V1 from the redundant channel CH (n+1) to the voltage output terminal TO_1.

The PMIC 31 sets the signal ALT to the “H” level and notifies the memory controller 20 that abnormality has occurred.

### 1.3 Effects According to Present Embodiment

With the effects according to the present embodiment, it is possible to provide a power supply device capable of compensating the supply of the power supply voltage. The effects will be described.

For example, in a case where the output abnormality occurs in any of the channels CH, the PMIC turns off not only the channel CH but also the other channels CH in order to protect a coupling destination circuit. For example, in a case where the output abnormality occurs due to the constant failure of the PMIC, the abnormality is not eliminated even if the power is turned on again. In such a case, the power supply voltage is not supplied to the memory system 3, so that the memory system 3 does not operate. Therefore, the host cannot access data in the non-volatile memory 10. For example, the chip size of the PMIC is relatively small. For this reason, the PMIC is often implemented by a wafer-level chip size package (CSP). For example, in order to maintain mechanical strength, the PMIC is fixed with an underfill, and replacement thereof is difficult.

Meanwhile, in the configuration according to the present embodiment, the PMIC 31 includes a surplus channel CH (redundant channel CH) for compensating the power supply voltage. In a case of detecting the output abnormality, the PMIC 31 can stop the output of the power supply voltage from the channel CH in which the output abnormality is detected. The PMIC 31 can control the load switch LSW to electrically couple the redundant channel CH and the voltage output terminal TO corresponding to the channel CH in which the output abnormality has occurred to each other. That is, the PMIC 31 can supply a voltage from the redundant channel CH to the voltage output terminal TO corresponding to the channel CH in which the output abnormality has occurred. As a result, the power supply device 30 can output the power supply voltage similarly to a normal state even if the output abnormality occurs in the PMIC 31. That is, the power supply device 30 can compensate the supply of the power supply voltage. Even if the abnormality occurs in the power supply device 30, the memory system 3 can operate normally because the power supply voltage is supplied from the power supply device 30. That is, the host 2 can access data in the non-volatile memory 10. Therefore, the reliability of the memory system 3 can be improved.

Furthermore, with the configuration according to the present embodiment, in a case where the output abnormality occurs, the PMIC 31, that is, the power supply device 30 can notify the memory controller 20 of the occurrence of the abnormality. For example, by notifying a user of the abnormality and prompting the user to back up data, a situation in which the user cannot access data in the non-volatile memory 10 can be avoided. Therefore, the reliability of data can be improved.

### 2. Second Embodiment

Next, a second embodiment will be described. In the second embodiment, the configuration of a power supply device 30 different from that of the first embodiment will be described. Hereinafter, a description will be given focusing on differences from the first embodiment.

### 2.1 Configuration of Power Supply Device

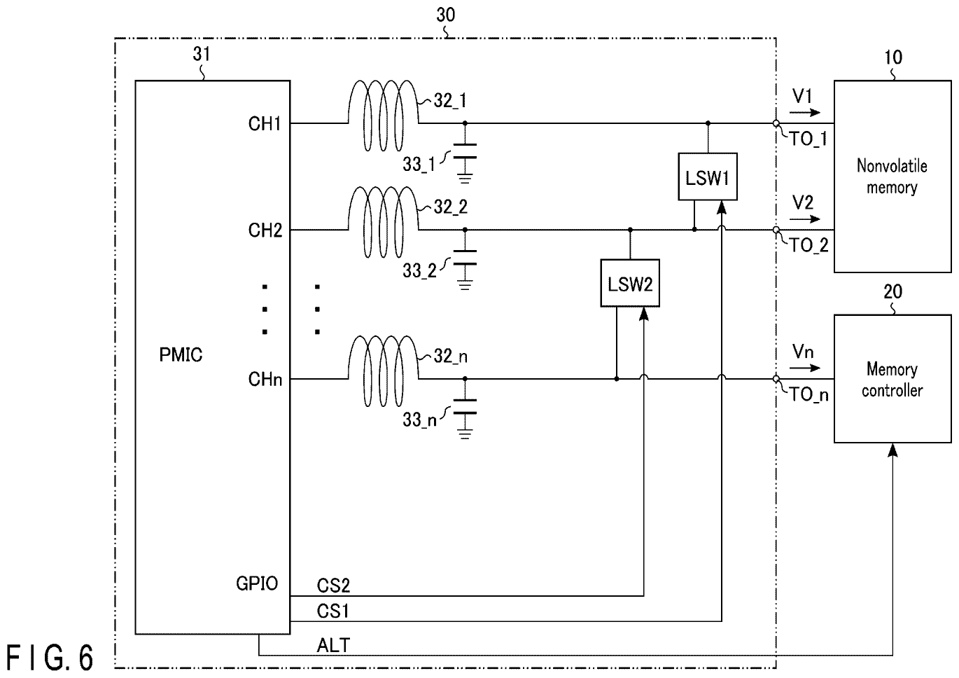

First, an example of the configuration of the power supply device 30 will be described with reference to FIG. 6. FIG. 6 is a circuit diagram illustrating an example of the circuit configuration of the power supply device 30.

As illustrated in FIG. 6, the power supply device 30 includes a PMIC 31, a plurality of load switches LSW, a plurality of inductor elements 32, a plurality of capacitor elements 33, and a plurality of voltage output terminals TO. In the example illustrated in FIG. 6, the power supply device 30 includes n inductor elements 32_1 to 32_n, n capacitor elements 33_1 to 33_n, and n voltage output terminals TO_1 to TO_n. The n inductor elements 32_1 to 32_n and the n capacitor elements 33_1 to 33_n are coupled in the same manner as in the first embodiment.

The number of channels CH of the PMIC 31 of the present embodiment is the same as the number of the voltage output terminals TO of the power supply device 30. That is, a redundant channel CH is not provided. A plurality of channels CH can be commonly coupled via the load switches LSW. That is, the plurality of voltage output terminals TO can be coupled to one channel CH. For example, in a case where output abnormality occurs, the voltage output terminal TO corresponding to the channel CH in which the output abnormality has occurred is electrically coupled to another channel CH via the load switch LSW. For example, as the channel CH coupled to the voltage output terminal TO via the load switch LSW, the channel CH that can supply a voltage within the operation guarantee range of an external circuit (a non-volatile memory 10 or a memory controller 20) to which the voltage output terminal TO is coupled is selected. That is, the voltage value of the output voltage of the channel CH coupled to the voltage output terminal TO via the load switch LSW can be included in the voltage guarantee range of the voltage output from the voltage output terminal TO.

More specifically, in the example illustrated in FIG. 6, the power supply device 30 outputs voltages V1 to Vn from the n voltage output terminals TO_1 to TO_n, respectively. Meanwhile, the PMIC 31 includes n channels CH1 to CHn. In the present embodiment, the n channels CH1 to CHn are coupled to the n voltage output terminals TO_1 to TO_n of the power supply device 30, respectively. Each channel CH is configured to be further couplable to one or more voltage output terminals TO via one or more load switches LSW. In the example illustrated in FIG. 6, the channel CH1 and the voltage output terminal TO_1 are coupled to one end of the load switch LSW1, and the channel CH2 and the voltage output terminal TO_2 are coupled to the other end. Thus, the channel CH1 is configured to be couplable to the voltage output terminal TO_2 via the load switch LSW1. In other words, the channel CH2 is configured to be couplable to the voltage output terminal TO_1 via the load switch LSW1. For example, the voltage guarantee range of the voltage V1 output from the channel CH1 and the voltage guarantee range of the voltage V2 output from the channel CH2 at least partially overlap. For example, the lower limit value of the voltage V1 is VIL, and the upper limit value of the voltage V1 is V1H. In a case where the channel CH2 is coupled to the voltage output terminal TO_1 via the load switch LSW1, the output voltage V2 of the channel CH2, the lower limit value VIL, and the upper limit value V1H suitably have a relationship of VIL≤V2≤V1H. For example, the lower limit value of the voltage V2 is V2L, and the upper limit value of the voltage V2 is V2H. In a case where the channel CH1 is coupled to the voltage output terminal TO_2 via the load switch LSW1, the output voltage V1 of the channel CH1, the lower limit value V2L, and the upper limit value V2H suitably have a relationship of V2L≤V1≤V2H.

Furthermore, the channel CH2 and the voltage output terminal TO_2 are coupled to one end of the load switch LSW2, and the channel CHn and the voltage output terminal TO_n are coupled to the other end. Thus, the channel CH2 is configured to be couplable to the voltage output terminal TO_n via the load switch LSW2. In other words, the channel CHn is configured to be couplable to the voltage output terminal TO_2 via the load switch LSW2. The voltage guarantee range of the voltage V2 output from the channel CH2 and the voltage guarantee range of the voltage Vn output from the channel CHn at least partially overlap.

In a case of detecting the abnormality (output abnormality) of the voltage output from any of the channels CH1 to CHn, the PMIC 31 stops the output of the voltage from the channel CH. The PMIC 31 outputs the voltage to the corresponding voltage output terminal TO using another channel CH coupled via the load switch LSW.

### 2.2 Specific Example in Case where PMIC Detects Output Abnormality

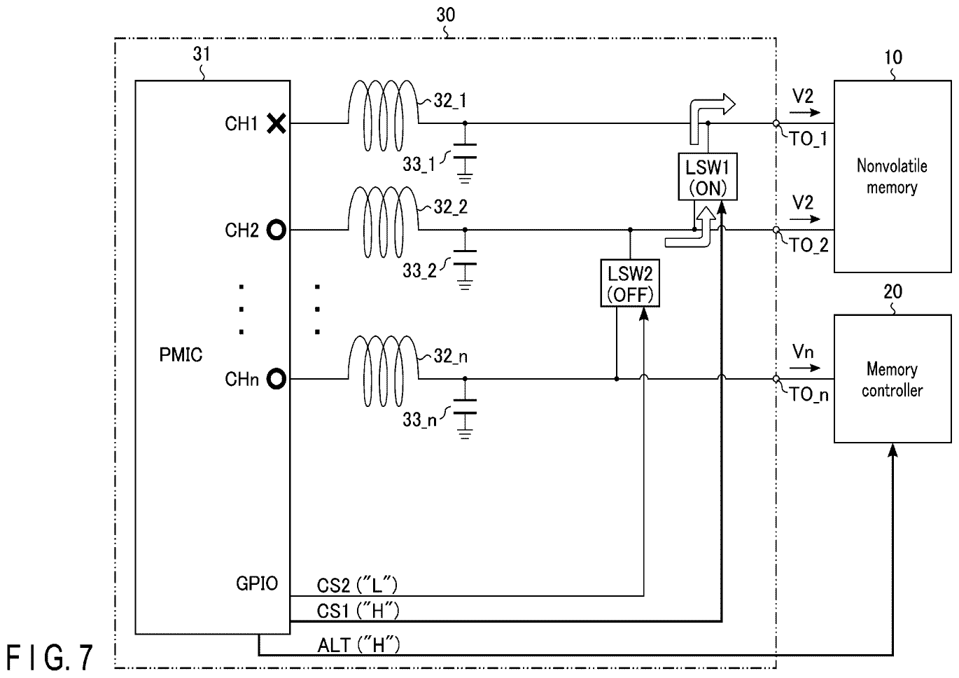

Next, a specific example in a case where the PMIC 31 detects the output abnormality will be described with reference to FIG. 7. FIG. 7 is a diagram illustrating the specific example of the power supply device 30 in a state where the PMIC 31 detects the output abnormality.

As illustrated in FIG. 7, for example, in a case where abnormality is detected in the output voltage of the channel CH1, the PMIC 31 stops the output of the voltage V1 from the channel CH1.

In this state, for example, the PMIC 31 sets the control signal CS1 to the “H” level and turns on the load switch LSW1. The PMIC 31 sets the other control signal CS2 to the “L” level and turns off the load switch LSW2. As a result, the channel CH2 and the voltage output terminal TO_1 are electrically coupled to each other. The PMIC 31 supplies the voltage V2 from the channel CH2 to the voltage output terminals TO_1 and TO_2. If the voltage V2 is a voltage value within the operation guarantee range of the coupling destination circuit of the voltage output terminal TO_1, the coupling destination circuit (non-volatile memory 10) can operate.

The PMIC 31 sets the signal ALT to the “H” level and notifies the memory controller 20 that abnormality has occurred.

### 2.3 Effects According to Present Embodiment

With the configuration according to the present embodiment, the power supply device 30 can couple the plurality of voltage output terminals TO to one channel CH of the PMIC 31 via the load switch LSW. In a case of detecting the output abnormality, the PMIC 31 can stop the output of the power supply voltage from the channel CH in which the output abnormality is detected. The PMIC 31 can control the load switch LSW to electrically couple the voltage output terminal TO corresponding to the channel CH in which the output abnormality has occurred to another channel CH. That is, the PMIC 31 can supply the voltage from the other channel CH to the voltage output terminal TO corresponding to the channel CH in which the output abnormality has occurred via the load switch LSW. As a result, even if the output abnormality occurs in the PMIC 31, the power supply device 30 can output the power supply voltage from the voltage output terminal TO corresponding to the channel CH in which the output abnormality has occurred. That is, the power supply device 30 can compensate the supply of the power supply voltage. If the voltage value of the power supply voltage output from the voltage output terminal TO corresponding to the channel CH in which the output abnormality has occurred is included in the operation guarantee range of the coupling destination circuit, the memory system 3 can operate normally even if the abnormality occurs in the power supply device 30. That is, the host 2 can access data in the non-volatile memory 10. Therefore, the reliability of the memory system 3 can be improved.

Furthermore, with the configuration according to the present embodiment, in a case where the output abnormality occurs, the PMIC 31 can notify the memory controller 20 of the occurrence of the abnormality as in the first embodiment. For example, by notifying a user of the abnormality and prompting the user to back up data, a situation in which the user cannot access data in the non-volatile memory 10 can be avoided. Therefore, the reliability of data can be improved.

### 3. Third Embodiment

Next, a third embodiment will be described. In the third embodiment, the configuration of a power supply device 30 different from that of the first and second embodiments will be described. Hereinafter, a description will be given focusing on differences from the first and second embodiments.

### 3.1 Configuration of Power Supply Device

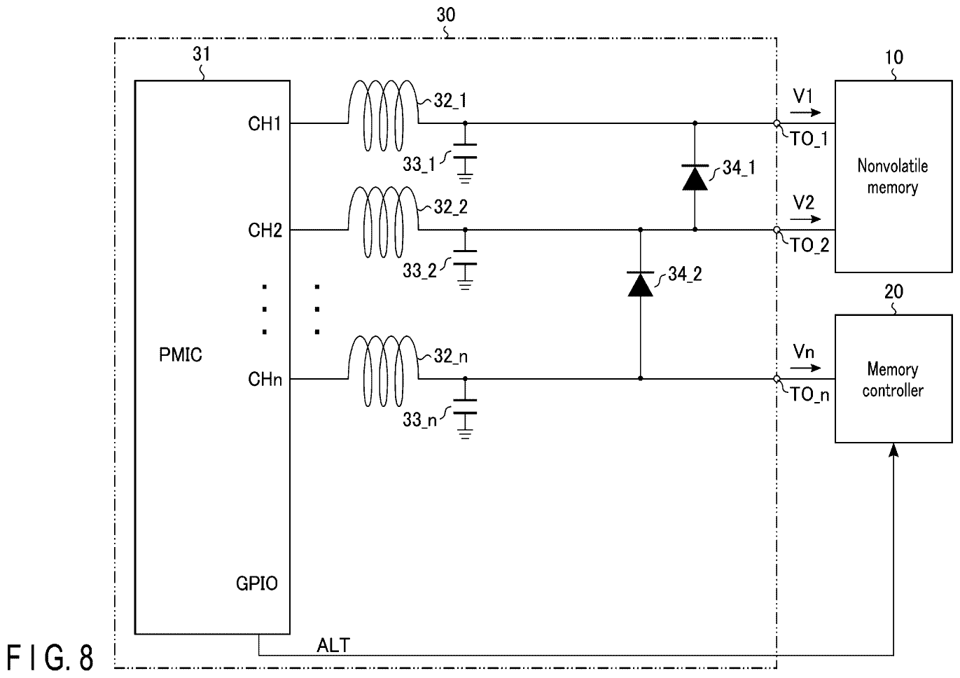

First, an example of the configuration of the power supply device 30 will be described with reference to FIG. 8. FIG. 8 is a circuit diagram illustrating an example of the configuration of the power supply device 30.

As illustrated in FIG. 8, the power supply device 30 includes a PMIC 31, a plurality of inductor elements 32, a plurality of capacitor elements 33, a plurality of diodes 34, and a plurality of voltage output terminals TO. In the example illustrated in FIG. 8, the power supply device 30 includes n inductor elements 32_1 to 32_n, n capacitor elements 33_1 to 33_n, and n voltage output terminals TO_1 to TO_n. The n inductor elements 32_1 to 32_n and the n capacitor elements 33_1 to 33_n are coupled in the same manner as in the first and second embodiments.

The present embodiment has a configuration in which the load switch LSW of the second embodiment is replaced with a diode 34. The diode 34 is coupled between a channel CH having a high output voltage and a voltage output terminal TO corresponding thereto and a channel CH having a low output voltage and a voltage output terminal TO corresponding thereto so as to form a reverse bias. In other words, a channel CH having a high output voltage and a voltage output terminal TO corresponding thereto are coupled to the cathode side of the diode 34, and a channel CH having a low output voltage and a voltage output terminal TO corresponding thereto are coupled to the anode side. As a result, in a normal state, the voltage of the channel CH having a high output voltage is suppressed from being applied to the side of the channel CH having a low output voltage.

The number of the channels CH of the PMIC of the present embodiment is the same as the number of the voltage output terminals TO of the power supply device 30 as in the second embodiment. A redundant channel CH is not provided. Two or more voltage output terminals TO may be coupled to one channel CH via one or more diodes 34. For example, in a case where output abnormality occurs, the voltage output terminal TO corresponding to the channel CH in which the output abnormality has occurred is electrically coupled to another channel CH via the diode 34. For example, as the channel CH coupled to the voltage output terminal TO via the diode 34, a channel CH having an output voltage lower than that of the channel CH coupled to the voltage output terminal TO without the diode 34 and capable of supplying a voltage within the operation guarantee range of an external circuit is selected. That is, the voltage value of a voltage obtained by subtracting voltage drop due to the diode 34 from the output voltage of the channel CH coupled to the voltage output terminal TO via the diode 34 can be included in the voltage guarantee range of a voltage output from the voltage output terminal TO.

More specifically, in the example illustrated in FIG. 8, the power supply device 30 outputs voltages V1 to Vn from the n voltage output terminals TO_1 to TO_n, respectively. Meanwhile, the PMIC 31 includes n channels CH1 to CHn. In the present embodiment, the n channels CH1 to CHn are coupled to the n voltage output terminals TO_1 to TO_n of the power supply device 30, respectively. Each channel CH is coupled to a voltage output terminal TO corresponding to a channel CH having an output voltage lower than that of the channel CH via the diode 34 coupled to a reverse bias. In the example illustrated in FIG. 8, the output voltage V1 of a channel CH1 and the output voltage V2 of a channel CH2 have a relationship of V1>V2. In this case, the channel CH1 and the voltage output terminal TO_1 are coupled to the cathode of a diode 34_1, and the channel CH2 and the voltage output terminal TO_2 are coupled to the anode of the diode 34_1. Therefore, the channel CH1 is coupled to the channel CH2 and the voltage output terminal TO_2 via the diode 34_1 coupled to the reverse bias. For example, in a case where the channel CH1 is turned off, the PMIC 31 can supply a voltage from the channel CH2 to the voltage output terminal TO_1 via the diode 34_1. For example, the lower limit value of the operation guarantee voltage of an external circuit (non-volatile memory 10) to which the voltage output terminal TO_1 is coupled is VL, and the upper limit value is VH. A drop voltage due to the diode 34 is VD. The output voltage V2 of the channel CH2, the drop voltage VD, the lower limit value VL, and the upper limit value VH suitably have a relationship of VL≤(V2−VD)≤VH.

The output voltage V2 of the channel CH2 and the output voltage Vn of the channel CHn have a relationship of V2>Vn. In this case, the channel CH2 and the voltage output terminal TO_2 are coupled to the cathode of a diode 34_2, and the channel CHn and the voltage output terminal TO_n are coupled to the anode of the diode 34_2. Therefore, the channel CH2 is coupled to the channel CHn and the voltage output terminal TO_n via the diode 34_2 coupled to the reverse bias. For example, in a case where the channel CH2 is turned off, the PMIC 31 can supply a voltage from the channel CHn to the voltage output terminal TO_2 via the diode 34_2.

In the PMIC 31 of the present embodiment, the control signal CS described using the first and second embodiments is eliminated.

### 3.2 Specific Example in Case where PMIC Detects Output Abnormality

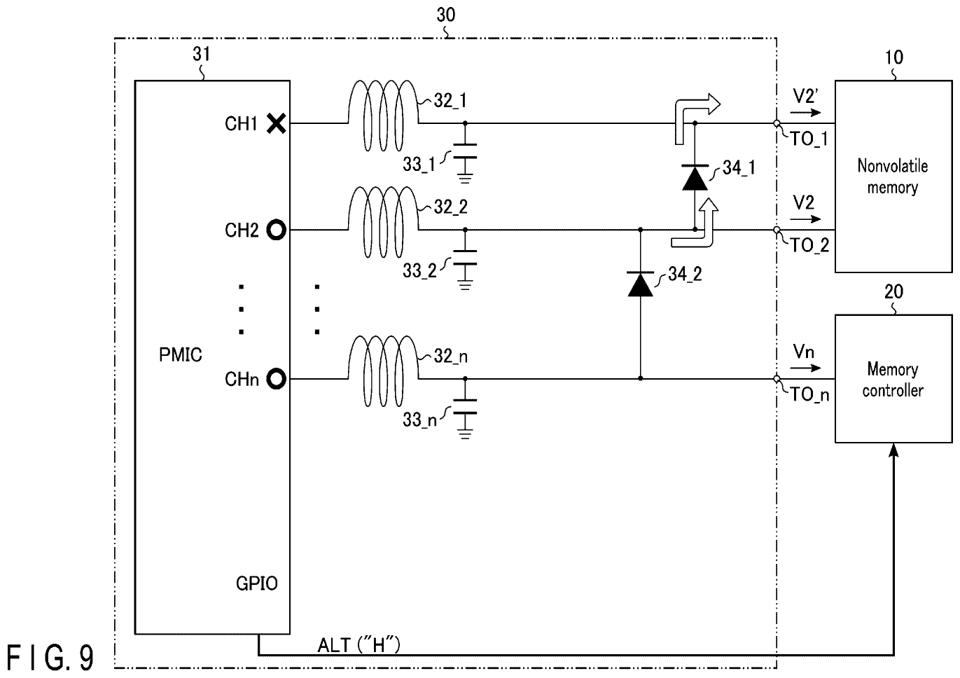

Next, a specific example in a case where the PMIC 31 detects output abnormality will be described with reference to FIG. 9. FIG. 9 is a diagram illustrating the specific example of the power supply device 30 in a state where the PMIC 31 detects the output abnormality.

As illustrated in FIG. 9, for example, in a case where abnormality is detected in the output voltage of the channel CH1, the PMIC 31 stops the output of the voltage V1 from the channel CH1. As a result, a voltage V2′ (=V2−VD) obtained by subtracting voltage drop due to the diode 34_1 from the output voltage V2 of the channel CH2 is supplied to the voltage output terminal TO_1.

The PMIC 31 sets the signal ALT to the “H” level and notifies the memory controller 20 of the occurrence of the abnormality.

### 3.3 Effects According to Present Embodiment

With the configuration according to the present embodiment, the power supply device 30 can couple the plurality of voltage output terminals TO to one channel CH of the PMIC31 via the diode 34. In a case of detecting the output abnormality, the PMIC 31 can stop the output of the voltage from the channel CH in which the output abnormality is detected. As a result, the PMIC 31 can supply, via the diode 34, a voltage obtained by subtracting voltage drop due to the diode 34 from the power supply voltage of the other channel CH to the voltage output terminal TO corresponding to the channel CH in which the output abnormality has occurred. That is, the power supply device 30 can compensate the supply of the power supply voltage. If the voltage value of the voltage output from the voltage output terminal TO corresponding to the channel CH in which the output abnormality has occurred is included in the operation guarantee range of the coupling destination circuit, the memory system 3 can operate normally even if the abnormality occurs in the power supply device 30. That is, the host 2 can access data in the non-volatile memory 10. Therefore, the reliability of the memory system 3 can be improved.

Furthermore, with the configuration according to the present embodiment, in a case where the output abnormality occurs, the PMIC 31 can notify the memory controller 20 of the occurrence of the abnormality as in the first and second embodiments. For example, by notifying a user of the abnormality and prompting the user to back up data, a situation in which the user cannot access data in the non-volatile memory 10 can be avoided. Therefore, the reliability of data can be improved.

### 4. Modifications

The power supply device according to the above embodiments include a power management integrated circuit (PMIC) and a plurality of voltage output terminals (TO). The PMIC includes a plurality of channels (CH) for outputting voltages and is capable of notifying an outside of output abnormality of at least one of the plurality of channels. The plurality of voltage output terminals include a first voltage output terminal (TO_1) coupled to a first channel (CH1) among the plurality of channels. In a case of detecting output abnormality of the first channel, the PMIC is configured to stop output of a first voltage (V1) from the first channel to the first voltage output terminal, electrically couple a second channel (CH (n+1)) different from the first channel among the plurality of channels to the first voltage output terminal, and output a second voltage (V1) from the second channel to the first voltage output terminal

The configurations according to the above embodiments can improve the reliability.

Note that the present invention is not limited to the above-described embodiments, and various modifications can be applied.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power supply device comprising:
a power management integrated circuit (PMIC) that includes a plurality of channels for outputting voltages and is capable of notifying an outside of output abnormality of at least one of the plurality of channels; and
a plurality of voltage output terminals,
wherein
the plurality of voltage output terminals include a first voltage output terminal coupled to a first channel among the plurality of channels, and
in a case of detecting output abnormality of the first channel, the PMIC is configured to stop output of a first voltage from the first channel to the first voltage output terminal, electrically couple a second channel different from the first channel among the plurality of channels to the first voltage output terminal, and output a second voltage from the second channel to the first voltage output terminal.

2. The power supply device according to claim 1, further comprising a plurality of load switches controlled by the PMIC,
wherein
a first terminal of each of the plurality of load switches is coupled to the second channel, and
a second terminal of each of the load switches is coupled to each of the plurality of voltage output terminals.

3. The power supply device according to claim 1, wherein the first voltage and the second voltage have the same voltage value.

4. The power supply device according to claim 2, wherein, in a case of detecting the output abnormality of the first channel, the PMIC is further configured to turn on a first load switch in which the second terminal is coupled to the first voltage output terminal among the plurality of load switches.

5. The power supply device according to claim 1, wherein the number of the plurality of channels is larger than the number of the plurality of voltage output terminals.

6. The power supply device according to claim 2, wherein the number of the plurality of load switches is the same as the number of the plurality of voltage output terminals.

7. The power supply device according to claim 1, further comprising:
an inductor including a first end coupled to the first channel and a second end coupled to the first voltage output terminal; and
a capacitor including a first electrode coupled to the second end of the inductor and the first voltage output terminal, and a second electrode grounded.

8. The power supply device according to claim 1, further comprising:
a first load switch including a first end coupled to the second channel and a second end coupled to the first voltage output terminal; and
a second load switch including a first end coupled to the third channel different from the first channel and the second channel among the plurality of channels and a second end coupled to a second voltage output terminal coupled to the second channel among the plurality of voltage output terminals,
wherein
the PMIC is further configured to control the first load switch and the second load switch.

9. The power supply device according to claim 8, wherein a voltage value of the second voltage is a lower limit value or more and an upper limit value or less of the first voltage.

10. The power supply device according to claim 8, wherein, in a case of detecting the output abnormality of the first channel, the PMIC is further configured to turn on the first load switch and turn off the second load switch.

11. The power supply device according to claim 7, wherein the number of the plurality of channels is the same as the number of the plurality of voltage output terminals.

12. The power supply device according to claim 1, further comprising:
a first diode including an anode coupled to the second channel and a cathode coupled to the first voltage output terminal; and
a second diode including an anode coupled to a third channel different from the first channel and the second channel among the plurality of channels and a cathode coupled to a second voltage output terminal among the plurality of voltage output terminals, the second voltage output terminal being coupled to the second channel.

13. The power supply device according to claim 12, wherein
a first output voltage value of the first channel is higher than a second output voltage value of the second channel, and
the second output voltage value of the second channel is higher than a third output voltage value of the third channel.

14. The power supply device according to claim 12, wherein the number of the plurality of channels is the same as the number of the plurality of voltage output terminals.

15. A memory system comprising:
the power supply device according to claim 1;
a non-volatile memory to which a voltage is supplied from the power supply device; and
a memory controller that is supplied with a voltage from the power supply device and is configured to control the non-volatile memory.

16. The memory system according to claim 15, wherein the non-volatile memory is a NAND flash memory.
